(19) United States
(12) Patent Application Publication
(10) Pub. No.: US 2004/0070427 A1
(43) Pub. Date: Apr. 15, 2004

(54) Semiconductor integrated circuit device having a leakage current cutoff circuit, constructed using MT-CMOS, for reducing standby leakage current

(75) Inventor: Satoru Miyagi, Kawasaki (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: Fujitsu Limited

(21) Appl. No.: 10/674,016

(22) Filed: Sep. 30, 2003

(30) Foreign Application Priority Data
Oct. 9, 2002 (JP) 2002-295854
Jul. 31, 2003 (JP) 2003-204739

(51) Int. Cl. H03K 3/00

(52) U.S. Cl. 327/100

(57) ABSTRACT

A semiconductor integrated circuit device has a high-threshold N-channel type MIS field effect transistor and a load circuit. The high-threshold N-channel type MIS field effect transistor is connected between a real high-potential power supply line and a pseudo high-potential power supply line. The load circuit has a low-threshold P-channel type MIS field effect transistor and a low-threshold N-channel type MIS field effect transistor. A first power supply terminal of the load circuit is connected to the pseudo high-potential power supply line, and a second power supply terminal of the load circuit is connected to a real low-potential power supply line.

### CROSS REFERENCE TO RELATED APPLICATION

This application is based upon and claims the benefit of priority from the prior Japanese Patent Applications No. 2002-295854, filed on Oct. 9, 2002 and No. 2003-204739, filed on Jul. 31, 2003, the entire contents of which are incorporated herein by reference.

### BACKGROUND OF THE INVENTION

1. Field of the Invention

The present invention relates to a semiconductor integrated circuit device and, more particularly, to a semiconductor integrated circuit device having a leakage current cutoff circuit, constructed using MT-CMOS, for reducing a standby leakage current.

2. Description of the Related Art

Recently, in semiconductor integrated circuits, there has been a growing need to reduce power consumption while retaining high-speed performance in order to meet the need for higher operating speeds in portable electronic apparatuses and for a longer battery life between charges. In semiconductor integrated circuits, if the supply voltage is lowered in order to reduce power consumption, the operating speed drops correspondingly; therefore, it becomes necessary to reduce the threshold voltage of MOS field effect transistors (Metal-Oxide-Semiconductor Field Effect Transistors, or more broadly, MIS field effect transistors (Metal-Insulation-Semiconductor Field Effect Transistors)). However, reducing the threshold voltage of MOS transistors gives rise to the problem of increased leakage current. To address this problem, there has been proposed in the art a technology called MT-CMOS (Multi-Threshold CMOS) which controls power by connecting a high-threshold transistor between the power supply line for a low-threshold transistor and the actual power supply line.

However, a semiconductor integrated circuit device having a leakage current cutoff circuit constructed using the prior known MT-CMOS has had problems such as an increase in layout area with each cell having a plurality of power supply lines, an inability to use existing standard cells in low-threshold MOS transistor circuits, and an inability to use a twin-well process which is generally less costly than a triple-well process. There is therefore a need to provide a semiconductor integrated circuit device that can use existing standard cells and can be constructed using a twin-well process, while suppressing an increase in layout area.

Further, in a semiconductor integrated circuit device having a leakage current cutoff circuit constructed using the prior known MT-CMOS, if the size of a circuit where power is turned ON and OFF at a time increases, there can arise a problem such as noise being generated there and causing malfunction of nearby circuits in operation; in view of this, there is also a need to provide a semiconductor integrated circuit device in which noise occurring at the time of turning ON and OFF a macro circuit is reduced so as not to cause a malfunction of other circuits.

The prior art and its associated problem will be described in detail later with reference to relevant drawings.

### SUMMARY OF THE INVENTION

An object of the present invention is to provide a semiconductor integrated circuit device that can use existing standard cells and can be constructed using a twin-well structure, while suppressing an increase in layout area. Another object of the present invention is to provide a semiconductor integrated circuit device in which noise occurring at the time of turning ON and OFF a macro circuit is reduced so as not to cause a malfunction of other circuits.

According to the present invention, there is provided a semiconductor integrated circuit device comprising a high-threshold N-channel type MIS field effect transistor connected between a real high-potential power supply line and a pseudo high-potential power supply line; and a load circuit having a low-threshold P-channel type MIS field effect transistor and a low-threshold N-channel type MIS field effect transistor, wherein a first power supply terminal of the load circuit is connected to the pseudo high-potential power supply line, and a second power supply terminal of the load circuit is connected to a real low-potential power supply line.

A back gate of the low-threshold P-channel type MIS field effect transistor may be connected to the pseudo high-potential power supply line, and a back gate of the low-threshold N-channel type MIS field effect transistor may be connected to the real low-potential power supply line. The semiconductor integrated circuit device may further comprise a waveshaping circuit which receives a control signal for controlling the high-threshold N-channel type MIS field effect transistor, and may perform waveshaping so that the control signal rises slowly, and wherein an output signal of the waveshaping circuit may be supplied to a gate of the high-threshold N-channel type MIS field effect transistor. The high-threshold N-channel type MIS field effect transistor may be configured as a source follower, and a voltage on the pseudo high-potential power supply line connected to the source of the high-threshold N-channel type MIS field effect transistor may rise slowly in response to the slowly rising output signal of the waveshaping circuit supplied to the gate.

Further, according to the present invention, there is provided a semiconductor integrated circuit device comprising a high-threshold N-channel type MIS field effect transistor connected between a real high-potential power supply line and a pseudo high-potential power supply line, the high-threshold N-channel type MIS field effect transistor being controlled by receiving a slowly rising control signal to a gate thereof; and a load circuit having a low-threshold P-channel type MIS field effect transistor and a low-threshold N-channel type MIS field effect transistor, wherein a first power supply terminal of the load circuit is connected to the pseudo high-potential power supply line, and a second power supply terminal of the load circuit is connected to a real low-potential power supply line.

According to the present invention, there is also provided a semiconductor integrated circuit device comprising a high-threshold MIS field effect transistor of a first conductivity type, connected between a first real power supply line and a first pseudo power supply line; a load circuit having a low-threshold MIS field effect transistor of the first conductivity type and a low-threshold MIS field effect transistor of a second conductivity type; and a level conversion circuit which receives a control signal of a first level for controlling the high-threshold MIS field effect transistor of the first conductivity type, and which converts the control signal of the first level into a control signal of a second level and supplies the control signal of the second level to a gate of the high-threshold MIS field effect transistor of the first conductivity type, wherein a first power supply terminal of the load circuit is connected to the first pseudo power supply line, and a second power supply terminal of the load circuit is connected to a second real power supply line.

The high-threshold MIS field effect transistor of the first conductivity type and the level conversion circuit may be together constructed as a module. The first level may be equal to a signal interface level of the load circuit, and the second level may be a level greater than the first level. The first real power supply line may be a real high-potential power supply line, the second real power supply line may be a real low-potential power supply line, the first pseudo power supply line may be a pseudo high-potential power supply line, and the high-threshold MIS field effect transistor of the first conductivity type may be a high-threshold N-channel type MIS field effect transistor, wherein a drain of the high-threshold N-channel type MIS field effect transistor may be connected to the real high-potential power supply line, a source thereof may be connected to the pseudo high-potential power supply line, and a back gate thereof may be connected to the real low-potential power supply line.

The first real power supply line may be a real high-potential power supply line, the second real power supply line may be a real low-potential power supply line, the first pseudo power supply line may be a pseudo high-potential power supply line, and the high-threshold MIS field effect transistor of the first conductivity type may be a high-threshold P-channel type MIS field effect transistor, wherein a source and back gate of the high-threshold P-channel type MIS field effect transistor may be connected to the real high-potential power supply line, and a drain thereof may be connected to the pseudo high-potential power supply line.

The semiconductor integrated circuit device may further comprise a waveshaping circuit which receives the output signal of the level conversion circuit, and performs waveshaping so that the output signal of the level conversion circuit rises slowly, and wherein an output signal of the waveshaping circuit may be supplied to a gate of the high-threshold MIS field effect transistor of the first conductivity type. The high-threshold MIS field effect transistor of the first conductivity type may be configured as a source follower, and a voltage on the first pseudo power supply line connected to the source of the high-threshold MIS field effect transistor of the first conductivity type may rise slowly in response to the slowly rising output signal of the waveshaping circuit supplied to the gate.

A physical shield may be provided over a signal wiring line from the level conversion circuit to the high-threshold MIS field effect transistor of the first conductivity type. The semiconductor integrated circuit device may have a multilayered wiring structure, and the shield may be formed in a prescribed intermediate wiring layer, while a signal line of a signal interface level of the load circuit is formed in a wiring layer located above the prescribed intermediate wiring layer.

The waveshaping circuit may comprise a high-threshold final-stage MIS field effect transistor having a large gate length and a small gate width, or a plurality of high-threshold final-stage MIS field effect transistors connected in series. The waveshaping circuit may comprise a digital/analog converter. The load circuit may comprise a memory circuit, and the digital/analog converter may output a voltage that is lower than a normal operating voltage of the memory and that only guarantees the retention of stored contents, thereby achieving a reduction in backup standby power consumption.

According to the present invention, there is also provided a semiconductor integrated circuit device comprising a high-threshold MIS field effect transistor of a first conductivity type, connected between a first real power supply line and a first pseudo power supply line; and a load circuit having a low-threshold MIS field effect transistor of the first conductivity type and a low-threshold MIS field effect transistor of a second conductivity type, wherein a first power supply terminal of the load circuit is connected to the first pseudo power supply line, and a second power supply terminal of the load circuit is connected to a second real power supply line, wherein the first pseudo power supply line is brought outside a chip.

Further, according to the present invention, there is also provided a semiconductor integrated circuit device comprising a high-threshold MIS field effect transistor of a first conductivity type, connected between a first real power supply line and a first pseudo power supply line; and a load circuit having a low-threshold MIS field effect transistor of the first conductivity type and a low-threshold MIS field effect transistor of a second conductivity type, wherein a first power supply terminal of the load circuit is connected to the first pseudo power supply line, and a second power supply terminal of the load circuit is connected to a second real power supply line, wherein the first real power supply line is brought outside a chip.

### BRIEF DESCRIPTION OF THE DRAWINGS

The present invention will be more clearly understood from the description of the preferred embodiments as set forth below with reference to the accompanying drawings, wherein:

FIGS. 1A, 1B, 1C, 1D, 1E, and 1F are circuit diagrams conceptually illustrating examples of semiconductor integrated circuit devices using prior art MT-CMOS technology;

FIGS. 2A and 2B are diagrams showing layout examples for the semiconductor integrated circuit device shown in FIG. 1A;

FIG. 3 is a schematic cross-sectional view for explaining one example of the fabrication process for the semiconductor integrated circuit device shown in FIG. 1A;

FIG. 4 is a diagram showing a layout example for the semiconductor integrated circuit device shown in FIG. 1D;

FIGS. 5A and 5B are schematic cross-sectional views for explaining examples of the fabrication process for the semiconductor integrated circuit device shown in FIG. 1D;

FIG. 6 is a circuit diagram conceptually illustrating a first embodiment of a semiconductor integrated circuit device according to the present invention;

FIG. 7 is a diagram showing the layout of the semiconductor integrated circuit device of FIG. 6;

FIG. 8 is a schematic cross-sectional view for explaining the fabrication process for the semiconductor integrated circuit device shown in FIG. 6;

FIGS. 9A, 9B, and 9C are circuit diagrams for explaining the configuration of a power supply switch section in the semiconductor integrated circuit device;

FIG. 10 is a block circuit diagram schematically showing a second embodiment of a semiconductor integrated circuit device according to the present invention;

FIGS. 11A and 11B are block circuit diagrams schematically showing a third embodiment of a semiconductor integrated circuit device according to the present invention;

FIG. 12 is a diagram schematically showing a configuration example of a semiconductor integrated circuit device to which the third embodiment shown in FIG. 11A is applied;

FIG. 13 is a block circuit diagram schematically showing a fourth embodiment of a semiconductor integrated circuit device according to the present invention;

FIG. 14 is a block circuit diagram schematically showing a fifth embodiment of a semiconductor integrated circuit device according to the present invention;

FIG. 15 is a cross-sectional view of a chip showing wiring layers for explaining the semiconductor integrated circuit device shown in FIG. 14;

FIG. 16 is a circuit diagram schematically showing a sixth embodiment of a semiconductor integrated circuit device according to the present invention;

FIG. 17 is a diagram for explaining the operation of the semiconductor integrated circuit device shown in FIG. 16;

FIG. 18 is a block circuit diagram schematically showing a seventh embodiment of a semiconductor integrated circuit device according to the present invention;

FIG. 19 is a block circuit diagram schematically showing an eighth embodiment of a semiconductor integrated circuit device according to the present invention; and

FIG. 20 is a block circuit diagram schematically showing a ninth embodiment of a semiconductor integrated circuit device according to the present invention.

### DESCRIPTION OF THE PREFERRED EMBODIMENTS

Before proceeding to the detailed description of the semiconductor integrated circuit device according to the present invention, the prior art semiconductor integrated circuit device and its associated problems will be described first, with reference to the drawings.

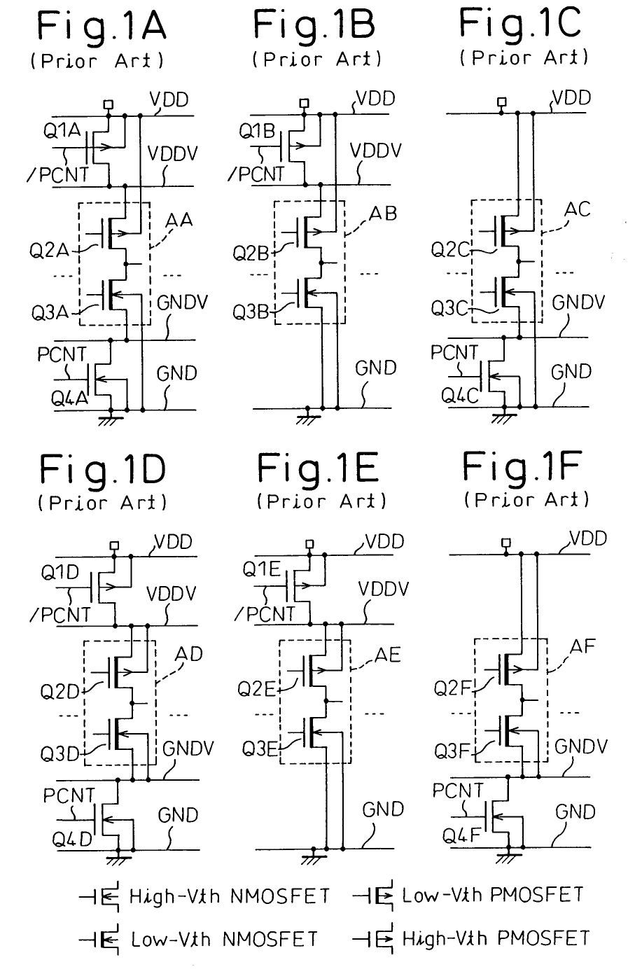

FIGS. 1A to 1F are circuit diagrams conceptually illustrating examples of semiconductor integrated circuit devices using prior art MT-CMOS technology, that is, circuit examples of semiconductor integrated circuit devices using prior art MT-CMOS technology are shown here. In FIGS. 1A to 1F, reference characters Q1A, Q1B, Q1D, and Q1E are high-threshold P-channel type MOS field effect transistors (High-Vth PMOSFETs: High-threshold PMOS transistors), Q4A, Q4C, Q4D, and Q4F are high-threshold N-channel type MOS field effect transistors (High-Vth NMOSFETs: High-threshold NMOS transistors), Q2A, Q2B, Q2C, Q2D, Q2E, and Q2F are low-threshold P-channel type MOS field effect transistors (Low-Vth PMOSFETs: Low-threshold PMOS transistors), and Q3A, Q3B, Q3C, Q3D, Q3E, and Q3F are low-threshold N-channel type MOS field effect transistors (Low-Vth NMOSFETs: Low-threshold NMOS transistors). Further, reference character VDD is a real high-potential power supply line, VDDV is a pseudo high-potential power supply line, GND is a real low-potential power supply line, and GNDV is pseudo low-potential power supply line. In the semiconductor integrated circuit devices of FIGS. 1A to 1F, load circuits (logic circuits or parts of logic circuits) AA to AF are each shown as comprising one low-threshold PMOS transistor and one low-threshold NMOS transistor connected in series, but it will be appreciated that various other configurations may be employed in practical circuits.

In the circuits shown in FIGS. 1A, 1B, 1C, and 1F, the back gates of the low-threshold PMOS transistors Q2A, Q2B, Q2C, and Q2F are connected to the real high-potential power supply line VDD and, in the circuits shown in FIGS. 1A, 1B, 1C, and 1E, the back gates of the low-threshold NMOS transistors Q3A, Q3B, Q3C, and Q3E are connected to the real low-potential power supply line GND. Further, in the circuits shown in FIGS. 1D and 1E, the back gates of the low-threshold PMOS transistors Q2D and Q2E are connected to the pseudo high-potential power supply line VDDV and, in the circuits shown in FIGS. 1D and 1F, the back gates of the low-threshold NMOS transistors Q3D and Q3F are connected to the pseudo low-potential power supply line GNDV.

In the circuits shown in FIGS. 1A, 1B, 1D, and 1E, the high-threshold PMOS transistors Q1A, Q1B, Q1D, and Q1E are each connected between the real high-potential power supply line VDD and the pseudo high-potential power supply line VDDV, and in the circuits shown in FIGS. 1A, 1C, 1D, and 1F, the high-threshold NMOS transistors Q4A, Q4C, Q4D, and Q4F are each connected between the real low-potential power supply line GND and the pseudo low-potential power supply line GNDV. In the circuits shown in FIGS. 1C and 1F, neither the pseudo high-potential power supply line (VDDV) nor the high-threshold PMOS transistor is provided, while in the circuits shown in FIGS. 1B and 1E, neither the pseudo low-potential power supply line (GNDV) nor the high-threshold NMOS transistor is provided.

The high-threshold PMOS transistors Q1A, Q1B, Q1D, and Q1E are supplied at their gates with a control signal (/PCNT) via a power control line /PCNT, and the high-threshold NMOS transistors Q4A, Q4C, Q4D, and Q4F are supplied at their gates with a power control signal (PCNT) via a power control line PCNT, to reduce leakage current, for example, during standby.

Semiconductor integrated circuit devices using MT-CMOS technology, such as shown in FIGS. 1A to 1F, are proposed in the prior art (refer, for example, to Japanese Unexamined Patent Publication No. H07-212217 and Japanese Unexamined Patent Publication No. H05-210976 (U.S. Pat. No. 5,274,601)).

That is, in the semiconductor integrated circuit devices using prior art MT-CMOS technology, the high-threshold PMOS transistor is connected between the real high-potential power supply line VDD and the pseudo high-potential power supply line VDDV and/or the high-threshold NMOS transistor is connected between the real low-potential power supply line GND and the pseudo low-potential power supply line GNDV, while the back gate of the low-threshold PMOS transistor is connected to the real high-potential power supply line VDD and/or the back gate of the low-threshold NMOS transistor is connected to the real low-potential power supply line GND.

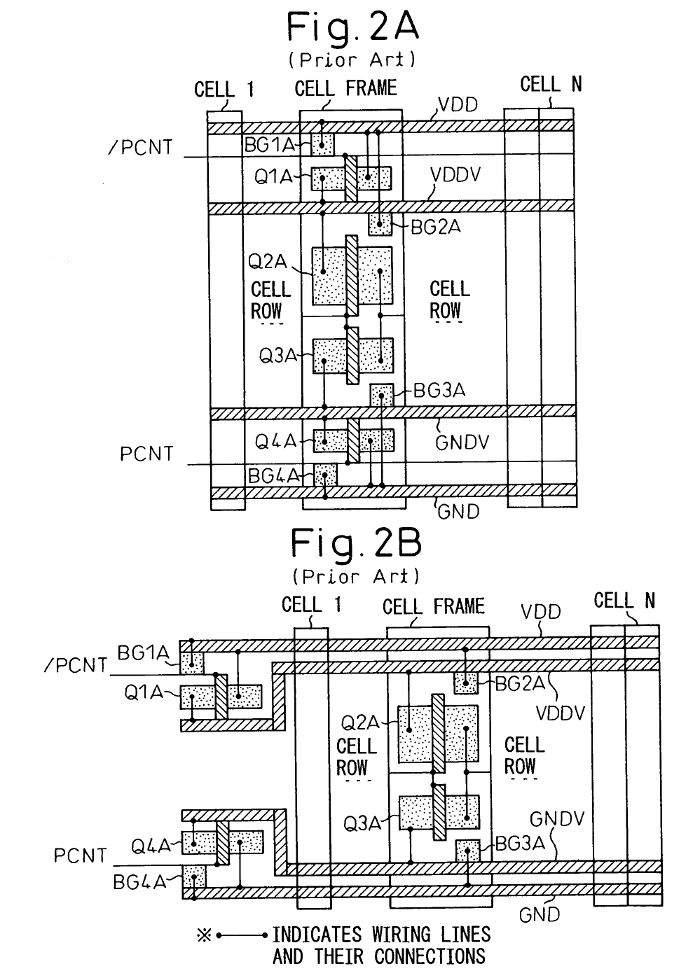

FIGS. 2A and 2B are diagrams showing layout examples for the semiconductor integrated circuit device shown in FIG. 1A.

First, in the layout shown in FIG. 2A, the high-threshold PMOS transistor Q1A, the low-threshold PMOS transistor Q2A, the low-threshold NMOS transistor Q3A, and the high-threshold NMOS transistor Q4A are constructed as one cell.

In the layout shown in FIG. 2B, on the other hand, the cell is constructed only with the low-threshold MOS transistors, and the high-threshold transistors connected to the respective power supply lines are arranged together in a separate place. That is, the low-threshold PMOS transistor Q2A and the low-threshold NMOS transistor Q3A are constructed as one cell, and the high-threshold PMOS transistor Q1A between the real high-potential power supply line VDD and the pseudo high-potential power supply line VDDV and the high-threshold NMOS transistor Q4A between the real low-potential power supply line GND and the pseudo low-potential power supply line GNDV are arranged together in a place separated from the cell.

In FIGS. 2A and 2B, reference characters BG1A to BG4A indicate the back gates of the respective transistors Q1A to Q4A.

Generally, it is desirable that the back gate of a transistor be located near the cell in order to stabilize the well potential. In the layouts shown in FIGS. 2A and 2B, the back gates BG2A and BG3A of the low-threshold PMOS transistor Q2A and low-threshold NMOS transistor Q3A constructed as one cell need to be connected to the real high-potential power supply line VDD and the real low-potential power supply line GND, respectively; accordingly, a total of four power supply lines, i.e., the real high-potential power supply line VDD, the pseudo high-potential power supply line VDDV, the pseudo low-potential power supply line GNDV, and the real low-potential power supply line GND, must be provided for each cell. In the case of the layouts of the semiconductor integrated circuit devices of FIGS. 1B and 1C, three power supply lines (VDD, VDDV, and GNDV in the case of FIG. 1B, and VDDV, GNDV, and GND in the case of FIG. 1C) must be provided for each cell.

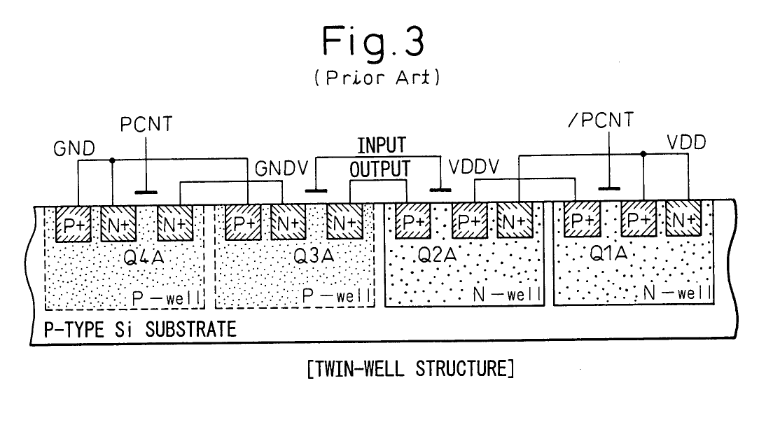

FIG. 3 is a schematic cross-sectional view for explaining one example of the fabrication process for the semiconductor integrated circuit device shown in FIG. 1A.

As shown in FIG. 3, the semiconductor integrated circuit device of FIG. 1A described above can be fabricated using a twin-well process. Likewise, the semiconductor integrated circuit devices of FIGS. 1B and 1C can also be fabricating using a twin-well process.

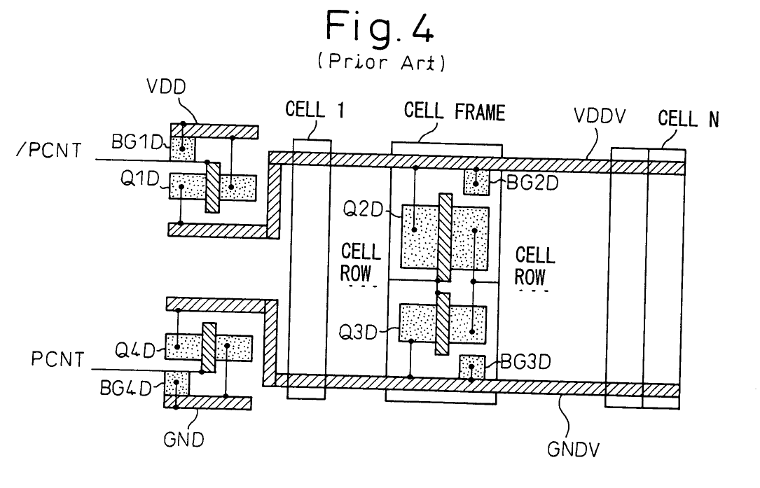

FIG. 4 is a diagram showing a layout example for the semiconductor integrated circuit device shown in FIG. 1D. In FIG. 4, reference characters BG2D and BG3D indicate the back gates of the transistors Q2D and Q3D, respectively.

As shown in FIG. 4, in the semiconductor integrated circuit device of FIG. 1D, the low-threshold PMOS transistor Q2D and the low-threshold NMOS transistor Q3D are constructed as one cell, and the high-threshold PMOS transistor Q1D between the real high-potential power supply line VDD and the pseudo high-potential power supply line VDDV and the high-threshold NMOS transistor Q4D between the real low-potential power supply line GND and the pseudo low-potential power supply line GNDV are arranged together in a place separated from the cell, as in the case of FIG. 2B. However, in the semiconductor integrated circuit device shown in FIG. 1D, as the back gates BG2D and BG3D of the low-threshold PMOS transistor Q2D and the low-threshold NMOS transistor Q3D need only be connected to the pseudo high-potential power supply line VDDV and the pseudo low-potential power supply line GNDV, respectively, only two power supply lines, i.e., the pseudo high-potential power supply line VDDV and the pseudo low-potential power supply line GNDV, need be provided for the cell.

The cell structure is the same for the layouts of the semiconductor integrated circuit devices of FIGS. 1E and 1F. However, in the semiconductor integrated circuit device of FIG. 1E, the two power supply lines are the pseudo high-potential power supply line VDDV and the real low-potential power supply line GND, and in the semiconductor integrated circuit device of FIG. 1F, the two power supply lines are the real high-potential power supply line VDD and the pseudo low-potential power supply line GNDV.

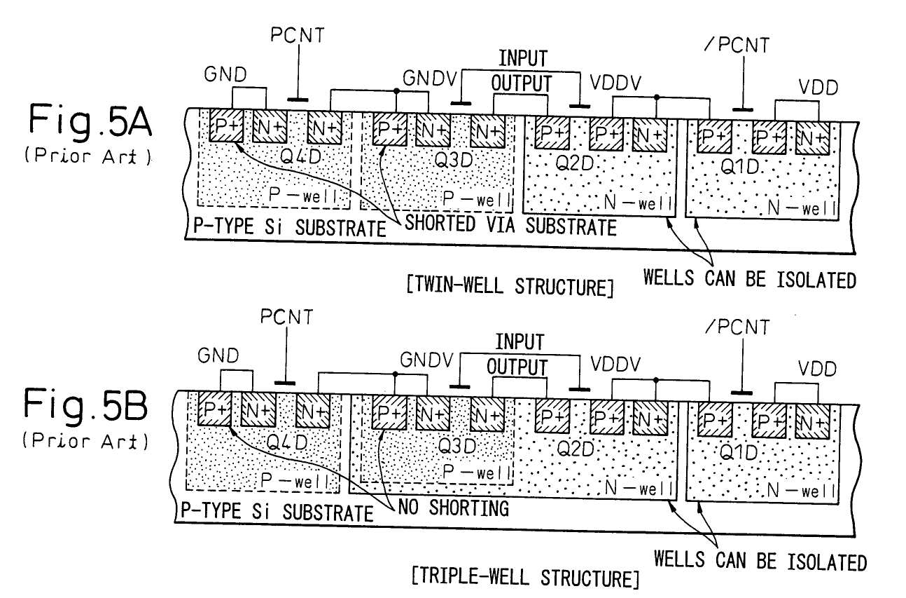

FIGS. 5A and 5B are schematic cross-sectional views for explaining further examples of the fabrication process for the semiconductor integrated circuit device shown in FIG. 1; more specifically, the fabrication process for the semiconductor integrated circuit device of FIG. 1D is illustrated here. FIGS. 5A and 5B each show the fabrication process for the semiconductor integrated circuit device of FIG. 1D in respectively different structures, that is, FIG. 5A shows the process for a twin-well structure and FIG. 5B the process for a triple-well structure.

As shown in FIG. 5A, when the semiconductor integrated circuit device of FIG. 1D is constructed in a twin-well structure, the back gates (P-type wells: P-wells) of the high-threshold NMOS transistor Q4D and the low-threshold NMOS transistor Q3D are connected to the real low-potential power supply line GND and the pseudo low-potential power supply line GNDV, respectively, but these are shorted together via the substrate (P-type silicon substrate). That is, the back gate (P-type well) of the high-threshold NMOS transistor Q4D is electrically connected to the back gate (P-type well) of the low-threshold NMOS transistor Q3D, thus shorting together the real low-potential power supply line GND and the pseudo low-potential power supply line GNDV. The problem of the real low-potential power supply line GND and the pseudo low-potential power supply line GNDV shorting together also occurs in the semiconductor integrated circuit device of FIG. 1F.

Further, as shown in FIG. 5A, when the semiconductor integrated circuit device of FIG. 1D is constructed in a twin-well structure, the back gates (N-type wells: N-wells) of the high-threshold PMOS transistor Q1D and the low-threshold PMOS transistor Q2D are connected to the real high-potential power supply line VDD and the pseudo high-potential power supply line VDDV, respectively, the shorting between the real high-potential power supply line VDD and the pseudo high-potential power supply line VDDV is avoided because of the isolation provided by the respective N-type wells (the back gate of the high-threshold PMOS transistor Q1D and the back gate of the low-threshold PMOS transistor Q2D). In the semiconductor integrated circuit device of FIG. 1E also, the back gate of the high-threshold PMOS transistor and the back gate of the low-threshold PMOS transistor are isolated by the respective N-type wells, avoiding the shorting between the real high-potential power supply line VDD and the pseudo high-potential power supply line VDDV.

On the other hand, as can be seen from FIG. 5B, when the semiconductor integrated circuit device of FIG. 1D is constructed in a triple-well structure, the back gates of the high-threshold NMOS transistor and low-threshold NMOS transistor, as well as the back gates of the high-threshold PMOS transistor and low-threshold PMOS transistor, are formed without shorting together. The same is true of the semiconductor integrated circuit devices of FIGS. 1E and 1F.

In the related art, there is proposed a semiconductor integrated circuit having a leakage current cutoff circuit designed in such a manner that power supply switches constructed from a plurality of high-threshold transistors, arranged around macro circuits constructed from low-threshold transistors, are turned ON and OFF at staggered time intervals with the aim to reduce noise to other macro circuits connected to the same power supply (refer, for example, to Japanese Patent Application No. 2002-092801).

There is also proposed a semiconductor storage device with provisions made to prevent memory cell data from being destroyed by power supply noise occurring at the time of ON/OFF switching in a configuration for reducing OFF-leakage current by providing an ON/OFF switch ON a power supply line of a peripheral circuit (refer, for example, to Japanese Unexamined Patent Publication No. 2000-298987 (U.S. Pat. No. 6,188,628).

As described above, the prior art semiconductor integrated circuit devices shown in FIGS. 1A, 1B, and 1C, for example, involve problems such as an increase in layout area with each cell having a plurality of power supply lines (VDD, VDDV, GND, and GNDV) and an inability to use existing standard cells in low-threshold MOS transistor circuits.

Further, the prior art semiconductor integrated circuit devices shown in FIGS. 1D and 1F, for example, involve the problem of being unable to use a twin-well fabrication process (twin-well structure) which is generally less costly than a triple-well process. Furthermore, in the case of the prior art semiconductor integrated circuit device shown in FIG. 1E, if the power supply switch (MT-CMOS switch) is constructed using a P-channel type MOS transistor (PMOS transistor), as the carriers are holes, the carrier mobility is low compared with the N-channel type in which the carriers are electrons; accordingly, if the voltage drop in the power supply switch is to be reduced below a prescribed value, there arises the problem that the PMOS transistor width increases, resulting in an increase in layout area.

With the recent trend toward higher functionality and larger capacity in semiconductor integrated circuit devices using the MT-CMOS technology described above, the circuit size is expected to increase further. As the size of the circuit where power is turned ON and OFF at a time increases, di/dt (change of current per unit time) increases, giving rise to a noise source which can cause a malfunction of nearby circuits in operation.

Embodiments of a semiconductor integrated circuit device according to the present invention will be described below with reference to the accompanying drawings.

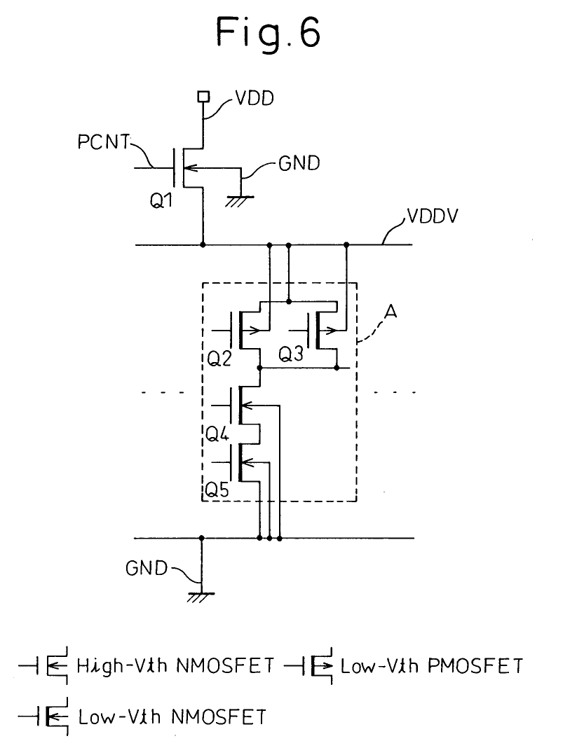

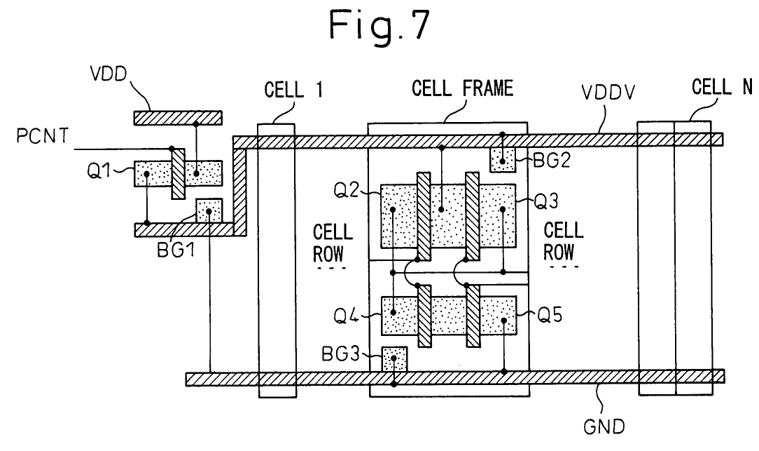

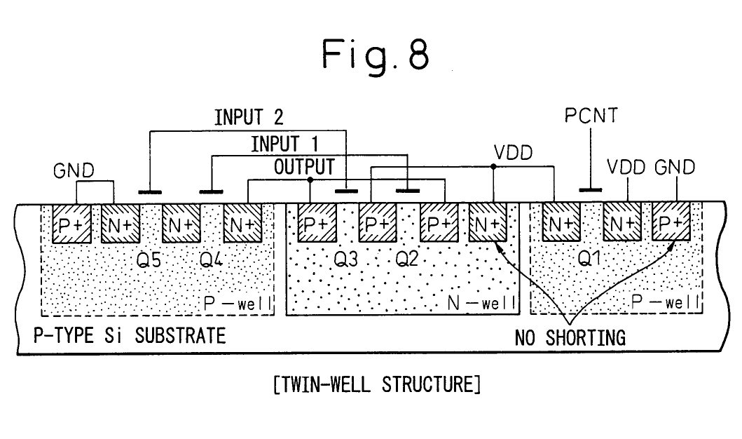

FIG. 6 is a circuit diagram conceptually illustrating a first embodiment of a semiconductor integrated circuit device according to the present invention. FIG. 7 is a diagram showing the layout of the semiconductor integrated circuit device of FIG. 6. FIG. 8 is a schematic cross-sectional view for explaining the fabrication process for the semiconductor integrated circuit device shown in FIG. 6; the process for a twin-well structure is shown here.

In FIGS. 6 to 8, reference character Q1 is a high-threshold N-channel type MOS field effect transistor (High-Vth NMOSFET: High-threshold NMOS transistor), Q2 and Q3 are low-threshold P-channel type MOS field effect transistors (Low-Vth PMOSFETs: Low-threshold PMOS transistors), and Q4 and Q5 are low-threshold N-channel type MOS field effect transistors (Low-Vth NMOSFETs: Low-threshold NMOS transistors). Further, reference character VDD is a real high-potential power supply line, VDDV is a pseudo high-potential power supply line, and GND is a real low-potential power supply line. In the semiconductor integrated circuit device of FIG. 6, a load circuit (logic circuit or parts of the logic circuit) A is shown as comprising the two low-threshold PMOS transistors Q2 and Q3 and the two low-threshold NMOS transistors Q4 and Q5, but it will be appreciated that various other configurations may be employed in a practical circuit. Here, the real high-potential power supply line VDD is supplied, for example, with a supply voltage of 0.7 V.

As shown in FIG. 6, the high-threshold NMOS transistor Q1 is connected between the real high-potential power supply line VDD and the pseudo high-potential power supply line VDDV, and the load circuit (cell) A is provided between the pseudo high-potential power supply line VDDV and the real low-potential power supply line GND. The load circuit A comprises the low-threshold PMOS transistors Q2 and Q3 connected in parallel and the low-threshold NMOS transistors Q4 and Q5 connected in series. More specifically, the sources of the low-threshold PMOS transistors Q2 and Q3 are connected in common to the pseudo high-potential power supply line VDDV, while the common drain of the low-threshold PMOS transistors Q2 and Q3 is connected to the drain of the low-threshold NMOS transistor Q4. Further, the source of the low-threshold NMOS transistor Q4 is connected to the drain of the low-threshold NMOS transistor Q5, whose source is connected to the real low-potential power supply line GND.

In the semiconductor integrated circuit device of the present embodiment, the back gates of the low-threshold PMOS transistors Q2 and Q3 are connected to the pseudo high-potential power supply line VDDV, and the back gates of the low-threshold NMOS transistors Q4 and Q5 are connected to the real low-potential power supply line GND. Here, the back gate of the high-threshold NMOS transistor Q1 is connected to the real low-potential power supply line GND. The high-threshold PMOS transistor Q1 is supplied at its gate with a power control signal (PCNT) via a power control line PCNT, to reduce leakage current, for example, during standby.

In the semiconductor integrated circuit device of the present embodiment, the back gate of the high-threshold NMOS transistor Q1 is connected to the real low-potential power supply line GND, the back gates of the low-threshold NMOS transistors Q4 and Q5 are connected to the real low-potential power supply line GND, and the back gates of the low-threshold PMOS transistors Q2 and Q3 are connected to the pseudo high-potential power supply line VDDV. That is, the back gates of the low-threshold PMOS transistors Q2 and Q3 are connected to the pseudo high-potential power supply line VDDV, as in the previously described cases of FIGS. 1D and 1E, but as the back gates are isolated by the N-type well of the low-threshold PMOS transistors Q2 and Q3 as shown in FIG. 8, shorting with other back gates via the substrate does not occur even when the circuit device is constructed in a twin-well structure.

Further, as shown in FIG. 7, the sources and back gates of the low-threshold PMOS transistors Q2 and Q3 are connected only to the pseudo high-potential power supply line VDDV, and the sources and back gates of the low-threshold NMOS transistors Q4 and Q5 are connected only to the real low-potential power supply line GND; as a result, existing standard cells can be used. Furthermore, as the power supply switch is constructed from the high-threshold NMOS transistor Q1, the layout area can be reduced compared with the case where the power supply switch is constructed from a P-channel MOS transistor.

In the semiconductor integrated circuit device of the present embodiment, as the transistor as the power supply switch is constructed from the high-threshold NMOS transistor Q1 unlike the prior art configuration (for example, the semiconductor integrated circuit device of FIG. 1B), it does not turn ON unless a voltage equal to or greater than the sum of the source voltage (VDDV) and the threshold voltage (Vth(Q1)) of the transistor Q1 is applied as the power control signal (PCNT); therefore, a voltage of, for example, “0 V” or “3 V (or 3.3 V)” is applied. That is, when 0 V is applied as the power control signal (PCNT), the transistor Q1 is OFF, and the leakage currents of the low-threshold transistors are thus cut OFF; on the other hand, when 3 V is applied as the power control signal (PCNT), the transistor Q1 is ON, causing the real high-potential power supply line VDD and the pseudo high-potential power supply line VDDV to conduct and thus enabling the load circuit to operate.

As shown in FIG. 7, in the layout of the semiconductor integrated circuit device of the present embodiment, the cell comprises the low-threshold PMOS transistors Q2 and Q3, the low-threshold NMOS transistors Q4 and Q5, and the back gates BG2 and BG3, and only the pseudo high-potential power supply line VDDV and the real low-potential power supply line GND need be provided as the power supplies; as a result, existing standard cells can be used without any modification. The circuit is constructed by arranging a plurality of cells (cell 1 to cell N) in a row in such a manner as to connect the power supplies, but a plurality of such rows may be arranged to construct the circuit.

Further, as shown in FIG. 7, the high-threshold NMOS transistor Q1 as the power supply switch and its back gate BG1 can be formed together in one place to achieve an optimum layout size; here, the transistor Q1 can be implemented using a plurality of transistors as a transistor width of several centimeters to several tens of centimeters may be required depending on the peak current that flows in the circuit.

As can be seen from FIG. 8, unlike the case of the prior art semiconductor integrated circuit device shown in FIG. 1D or 1F, the semiconductor integrated circuit device of the present embodiment, even when constructed in a twin-well structure, does not involve the problem of the back gates at different nodes shoring together via the substrate, and can thus be implemented without using a costly triple-well process.

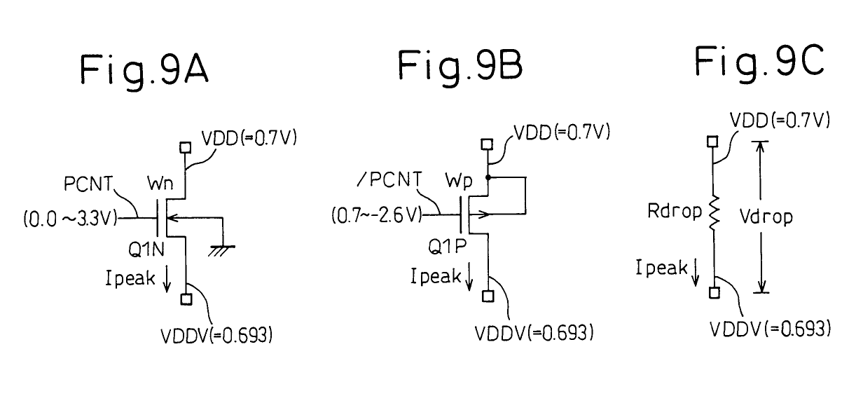

FIGS. 9A to 9C are circuit diagrams for explaining the configuration of the power supply switch section in the semiconductor integrated circuit device: FIG. 9A concerns the above-described first embodiment of the semiconductor integrated circuit device according to the present invention, and shows the configuration in which the power supply switch is constructed from an N-channel type MOS transistor (the high-threshold NMOS transistor Q1); FIG. 9B concerns a prior art semiconductor integrated circuit device (for example, the semiconductor integrated circuit device of FIG. 1B), and shows the configuration in which the power supply switch is constructed from a P-channel type MOS transistor (the high-threshold PMOS transistor Q1B); and FIG. 9C shows the configuration in which the transistor is replaced by a resistor Rdrop whose value is equivalent to the ON condition of the power supply switch.

Each of the transistors shown in FIGS. 9A and 9B is a MOS transistor driven with 3 V (or 3.3 V), that is, a high-threshold transistor such as the one generally used in a final stage I/O buffer. There is therefore no need to fabricate a new high-threshold transistor or to manage the characteristics. For the internal load circuit, usually available low-threshold MOS transistors can be used.

When a peak current Ipeak is expected to flow in the circuit, an allowable voltage drop value in the power switch needs to be specified in the specification at the design stage, and the load circuit is designed to be able to operate reliably even when the worst-case supply voltage drop occurs. Here, assume that the voltage of the real high-potential power supply line VDD is 0.7 V; then, if the allowable voltage drop in the power supply switch is specified at 1% or less, the voltage of the pseudo high-potential power supply line VDDV in the worst case is about 0.693 V.

At this time, when the power control signal (PCNT) in FIG. 9A is 3 V, or when the power control signal (/PCNT) in FIG. 9B is −2.6 V, the transistor (Q1N, Q1P) is turned ON and the peak current Ipeak flows; considering this, the transistor Q1N or Q1P can be replaced by the equivalent resistor Rdrop as shown in FIG. 9C. When FIGS. 9A and 9B are compared, transistor widths Wp and Wn must be optimized in order to adjust the ON resistances of the respective transistors if the same peak current Ipeak is to flow therethrough. The transistor widths Wp and Wn each may have to be set to several centimeters to several tens of centimeters depending on the current consumption of the entire chip, and this greatly affects the chip size.

Generally, a PMOS transistor in which the carriers are holes requires a larger transistor width Wp than does an NMOS transistor in which the carriers are electrons having higher mobility. In a specific example, it was shown, for example, by SPICE simulation that a PMOS transistor required a transistor width about three times that of an NMOS transistor. As a result, when the power supply switch is constructed from only a PMOS transistor as in the prior art, the layout area increases compared with the case where the power supply switch is constructed from only an NMOS transistor. Furthermore, in the case of a PMOS transistor, a negative voltage not usually used has to be applied to turn ON the transistor, but in the case of an NMOS transistor, the usual 3 V interface can be used.

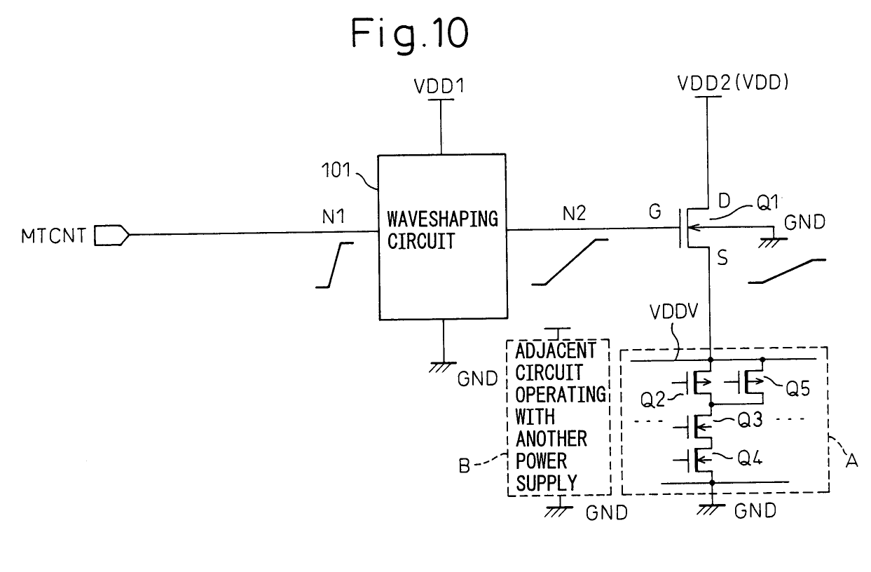

FIG. 10 is a block circuit diagram schematically showing a second embodiment of a semiconductor integrated circuit device according to the present invention.

As shown in FIG. 10, in the semiconductor integrated circuit device of the second embodiment, a control signal (a signal for controlling power ON and OFF) MTCNT is supplied via a waveshaping circuit 101 to the gate of a high-threshold NMOS transistor (power supply switch: MT-CMOS switch) Q1. That is, the control signal MTCNT is waveshaped by the waveshaping circuit 101 so that its waveform rises slowly, and the slowly rising waveform as the output signal of the waveshaping circuit 101 is supplied to the gate of the high-threshold NMOS transistor Q1. Here, as the high-threshold NMOS transistor Q1 is configured as a source follower, the voltage of the pseudo high-potential power supply line VDDV supplied via the source also rises slowly. Here, the control signal MTCNT is, for example, a 3 V interface signal, the supply voltage (VDD1) applied to the waveshaping circuit 101 is, for example, 3 V, and the voltage VDD2 (VDD) applied to the drain of the high-threshold NMOS transistor Q1 is, for example, 1.8 V.

With this configuration, even when the circuit size of the load circuit is large, and the current changes greatly at the time of power ON, for example, as the voltage of the pseudo high-potential power supply line VDDV rises slowly, di/dt (change of current per unit time) is held to a small value, and the generation of noise is thus suppressed. That is, at power ON to the load circuit A, as the supply voltage (VDDV) to the load circuit A rises slowly, the effects of noise, for example, on a circuit B adjacent to the load circuit A and operating with a different power supply can be reduced.

Further, the control signal MTCNT can be supplied from outside or inside of the semiconductor integrated circuit device (LSI). In the case that the control signal MTCNT is supplied from inside, or generated in the LSI, the control signal MTCNT is generated after logic operation is carried out in an logic circuit. In general, the logic circuit is, for example, constituted by standard cells, gate arrays, and the like, and designed within an acceptable load to be driven, and thereby a through rate in the nanosecond order is expected. Further, in the case that the control signal MTCNT is supplied from outside of the LSI, the control signal MTCNT should be passed through an I/O buffer, and thereby the through rate in the nanosecond order is expected. By considering noise reduction, the through rate is generally required in the order of milliseconds or microseconds, though it may be changed in accordance with a circuit scale to be switched. Therefore, the waveshaping circuit may be necessary within the LSI.

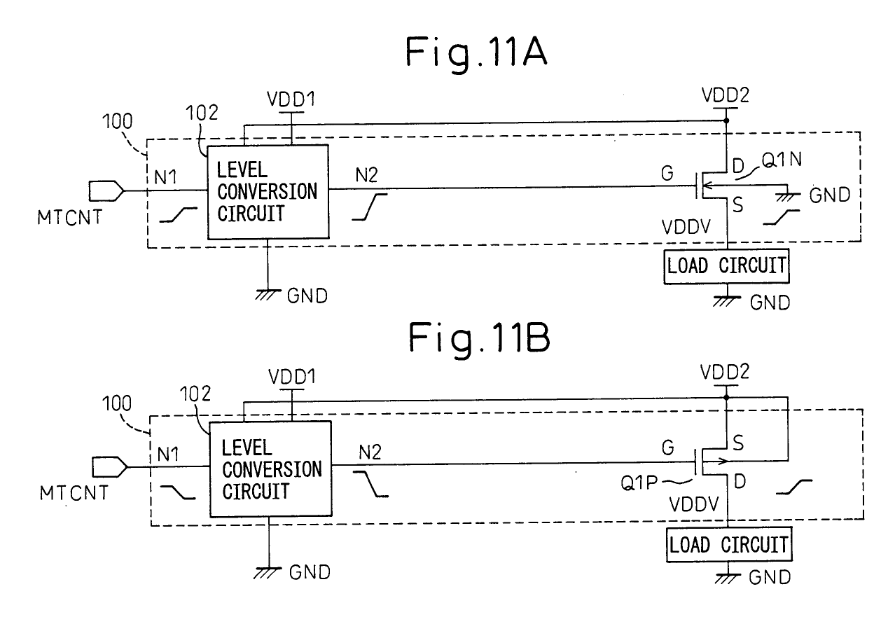

FIGS. 11A and 11B are block circuit diagrams schematically showing a third embodiment of a semiconductor integrated circuit device according to the present invention: FIG. 11A shows the configuration in which the power supply switch (MT-CMOS switch) is constructed from a high-threshold NMOS transistor Q1N, and FIG. 11B shows the configuration in which the power supply switch is constructed from a high-threshold PMOS transistor Q1P. In FIGS. 11A and 11B, the control signal MTCNT is, for example, a 1.8 V interface signal, the supply voltage (VDD1) applied to a level conversion circuit 102 is, for example, 3 V, and the voltage VDD2 applied to the drain of the high-threshold NMOS transistor Q1N (the source of the high-threshold PMOS transistor Q1P) is, for example, 1.8 V.

As shown in FIG. 11A or 11B, in the semiconductor integrated circuit device of the third embodiment, the control signal MTCNT (node N1), for example, at a 1.8 V interface level (the same interface level as the load circuit A constructed from low-threshold transistors) is converted by the level conversion circuit 102 into a 3 V series signal level (step-up: node N2), which is supplied to the gate of the high-threshold NMOS transistor Q1N or the high-threshold PMOS transistor Q1P. Here, as shown in FIG. 11A, the level conversion circuit 102 and the power supply switch (high-threshold NMOS transistor) Q1N are together constructed as a module (MT-CMOS cell) 100, or as shown in FIG. 11B, the level conversion circuit 102 and the power supply switch (high-threshold PMOS transistor) Q1P are together constructed as a module 100, to reduce the adverse effects on an adjacent circuit, etc. that may be caused by the output signal of the level conversion circuit 102 converted to the 3 V series signal level.

More specifically, the signal supplied to the gate of the power supply switch Q1N (Q1P), for example, is of a voltage higher than that of an ordinary transistor signal, and signal lines of different voltage levels being located adjacent to each other or crossing each other is not desirable from the point of view of cross talk and noise. In view of this, by constructing the level conversion circuit 102 and the power supply switch Q1N (Q1P) into a module, the high-voltage signal (the output signal of the level conversion circuit 102) is confined within the module, thereby reducing cross talk and noise.

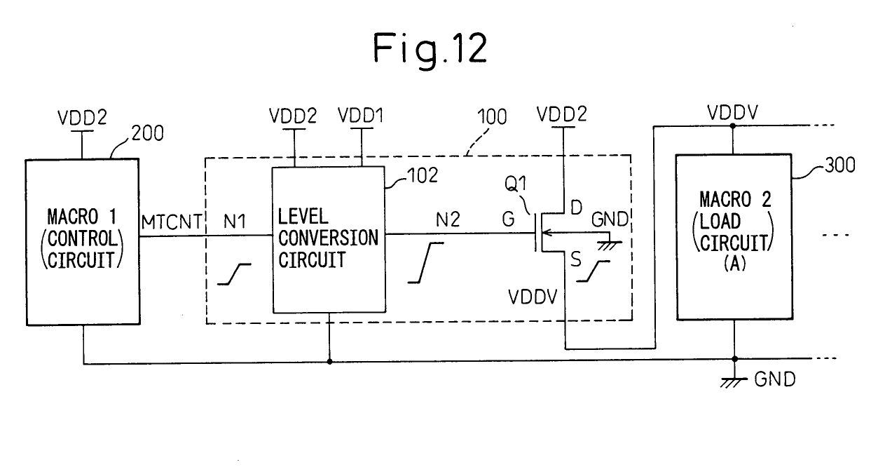

FIG. 12 is a diagram schematically showing a configuration example of a semiconductor integrated circuit device to which the third embodiment shown in FIG. 11A is applied. Here, the supply voltage (VDD1) applied to the level conversion circuit 102 is, for example, 3 V, and the supply voltage (VDD2) applied to a control circuit 200, the level conversion circuit 102, and the drain of the power supply switch Q1 is, for example, 1.8 V.

As shown in FIG. 12, the control signal MTCNT of the 1.8 V series signal level, output from the control circuit 200, is level-converted by the level conversion circuit 102 in the module 100 into a 3 V series signal, which is supplied to the gate of the power supply switch (high-threshold NMOS transistor) Q1. In this way, when the level conversion circuit 102 and the power supply switch Q1 are together constructed as the module 100, a signal of the same interface level as the internal logic power supply (for example, 1.8 V) can be used as the control signal MTCNT to be applied to the module 100, and the module 100 can be placed at a desired position within the chip. Then, the low voltage signal line need only be formed between macro circuits as usual (for example, between the control circuit 200 (macro 1) and load circuit 300 (macro 2)), and can be made less susceptible to the effects of the high voltage signal line (node N2).

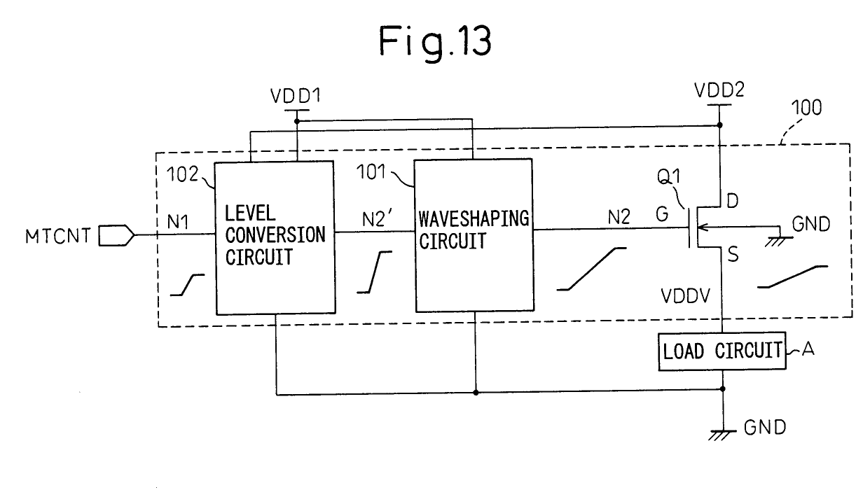

FIG. 13 is a block circuit diagram schematically showing a fourth embodiment of a semiconductor integrated circuit device according to the present invention.

As shown in FIG. 13, the semiconductor integrated circuit device of the fourth embodiment comprises both the waveshaping circuit 101 and the level conversion circuit 102 described above; that is, with the provision of the level conversion circuit 102, a signal of the same interface level as the internal logic power supply (for example, 1.8 V) can be used as the control signal MTCNT to be applied to the module 100, while making the construction less susceptible to the effects of the high-voltage signal line (node N2′), and with the provision of the waveshaping circuit 101, the voltage of the pseudo high-potential power supply line VDDV to the load circuit A is made to rise slowly, thereby suppressing the generation of noise.

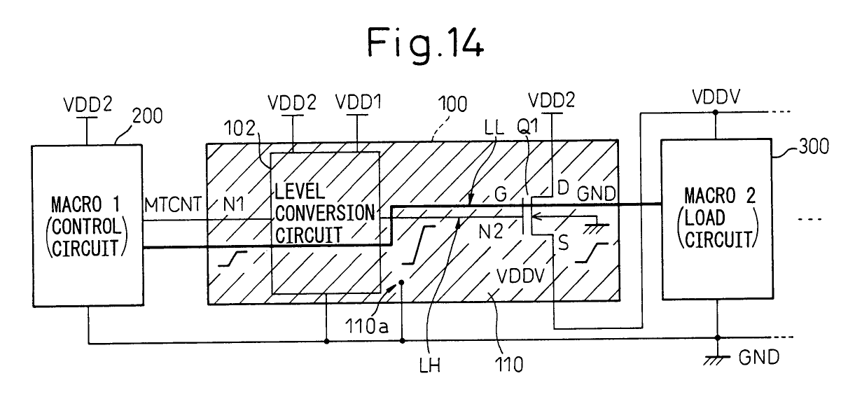

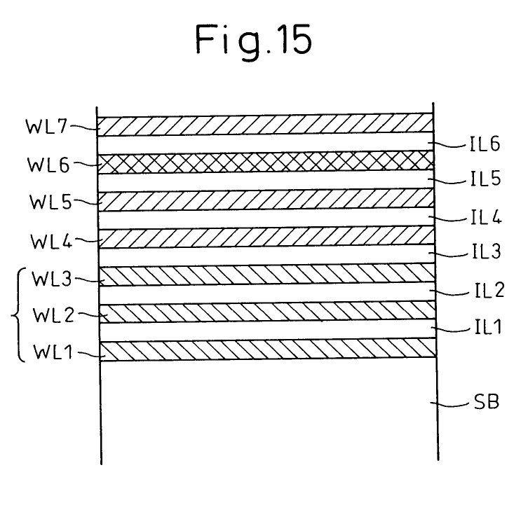

FIG. 14 is a block circuit diagram schematically showing a fifth embodiment of a semiconductor integrated circuit device according to the present invention, and FIG. 15 is a cross-sectional view of a chip showing wiring layers for explaining the semiconductor integrated circuit device shown in FIG. 14. In FIG. 15, reference character SB is a semiconductor substrate, WL1 to WL7 are the wiring layers, and IL1 to IL6 are insulating layers.

In the semiconductor integrated circuit device of the fifth embodiment, which is based on the semiconductor integrated circuit device of the third embodiment shown in FIG. 12, a shield layer 110 is provided above the module 100 that has a signal wiring line LH of a high-potential interface (3 V interface) which is the output of the level conversion circuit 102, and a signal wiring line LL of the same interface (1.8 V interface) as the internal logic power supply is provided above the shield layer 110.

That is, as shown in FIGS. 14 and 15, when the wiring layers WL1 to WL3, for example, are used for wiring of the transistor circuits, while using the wiring layer WL4 as the signal wiring line LH of the 3 V interface and the wiring layer WL5 for wiring of the power supplies VDD, VSS, etc., then the wiring layer WL6 above the module 100 that has the signal wiring line LH of the 3 V interface is grounded (grounding point 100a) as the shield layer 110, and the signal wiring line LL of the 1.8 V interface is formed in the wiring layer WL7 above the wiring layer WL6.

According to the semiconductor integrated circuit device of the fifth embodiment, the signal wiring line LL of the 1.8 V interface is shielded from the signal wiring line LH of the 3 V interface by the shield layer 110 (wiring layer WL6) so that the effects of the noise arising from the signal wiring line LH of the 3 V interface can be reduced.

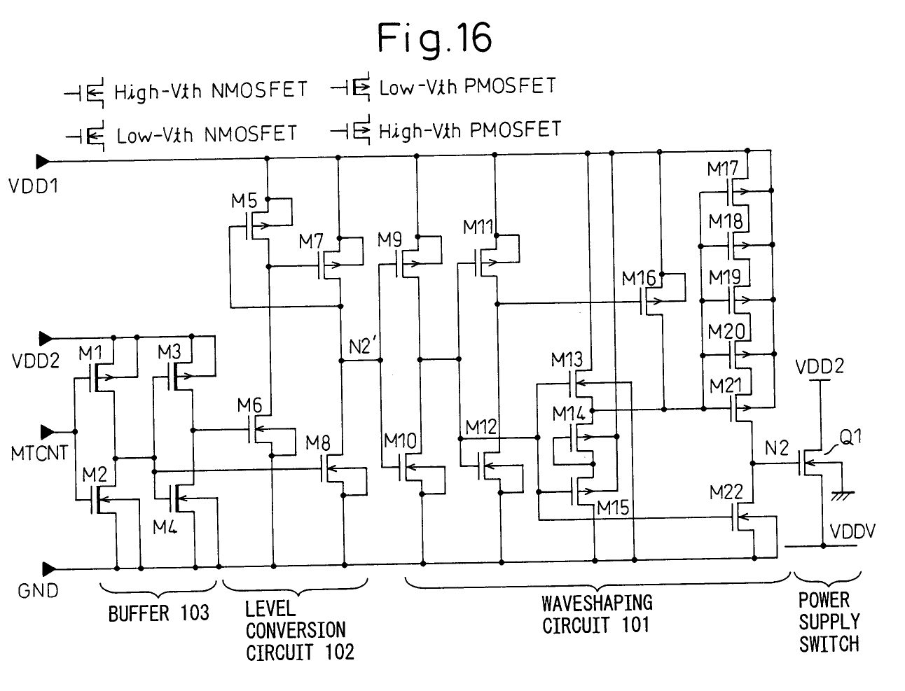

FIG. 16 is a circuit diagram schematically showing a sixth embodiment of a semiconductor integrated circuit device according to the present invention.

As shown in FIG. 16, the semiconductor integrated circuit device of the sixth embodiment comprises: a buffer 103 constructed from a two-stage inverter comprising low-threshold PMOS transistors (Low-Vth PMOSFETs) M1 and M3 and low-threshold NMOS transistors (Low-Vth NMOSFETs) M2 and M4; a level conversion circuit 102 having high-threshold PMOS transistors (High-Vth PMOSFETs) M5 and M7 and high-threshold NMOS transistors (High-Vth NMOSFETs) M6 and M8; a waveshaping circuit 101 having high-threshold PMOS transistors M9, M11, and M14 to M21 and high-threshold NMOS transistors M10, M12, M13, and M22; and a power supply switch Q1.

Here, the supply voltage VDD2 to which are connected the sources of the low-threshold PMOS transistors M1 and M3 in the buffer 103 is, for example, 1.3 V (or 1.8 V), while the supply voltage VDD1 to which are connected the sources of the high-threshold PMOS transistors M5 and M7 in the level conversion circuit 102 and the sources of the high-threshold PMOS transistors M11, M16, and M17 in the waveshaping circuit 101 is, for example, 2.5 V or (3 V). The high-threshold PMOS transistors M17 to M21 at the final stage of the waveshaping circuit 101 have a long gate length (transistor length) and a short gate width; by connecting a plurality of these transistors in series (five transistors in FIG. 16), the ON resistance is increased, thereby making the rise time of the waveform of the output signal (node N2) slow.

In this way, in the semiconductor integrated circuit device of the sixth embodiment, as the high-threshold PMOS transistors M17 to M21 at the final stage of the waveshaping circuit 101 are connected in series to increase the ON resistance and to make the output waveform slow, not only can the circuit size be reduced by reducing the number of transistors, but the control can be performed in a simple manner, compared with a waveshaping circuit that uses a digital/analog converter (D/A converter) described later.

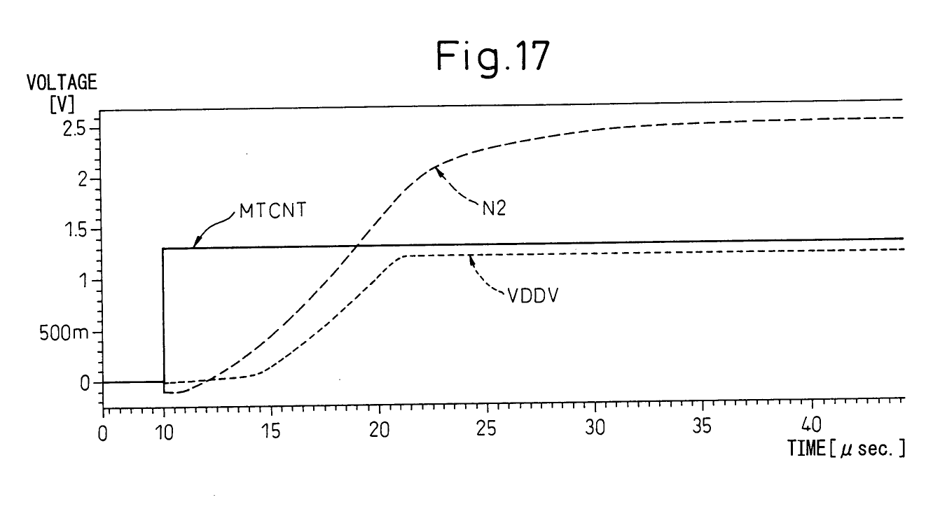

FIG. 17 is a diagram for explaining the operation of the semiconductor integrated circuit device shown in FIG. 16. In FIG. 17, the control signal MTCNT is a 1.3 V series signal, and the output signal (node N2) of the waveshaping circuit 101 is a 2.5 V series signal. Here, the voltage of the pseudo high-potential power supply line VDDV is about 1.2 V depending on a voltage drop.

As can be seen from FIG. 17, according to the semiconductor integrated circuit device shown in FIG. 16, the waveform of the output signal (N2) of the waveshaping circuit 101 rises slowly compared with the rising waveform of the control signal MTCNT and, because of the source follower action of the power supply switch (MT-CMOS switch) Q1 that receives the slowly rising signal waveform (N3) at its gate, the voltage of the pseudo high-potential power supply line VDDV also rises slowly. As a result, even when the circuit size of the load circuit (A) is large, and the current changes greatly at the time of power ON, for example, di/dt (change of current per unit time) is held to a small value, and the generation of noise is thus suppressed.

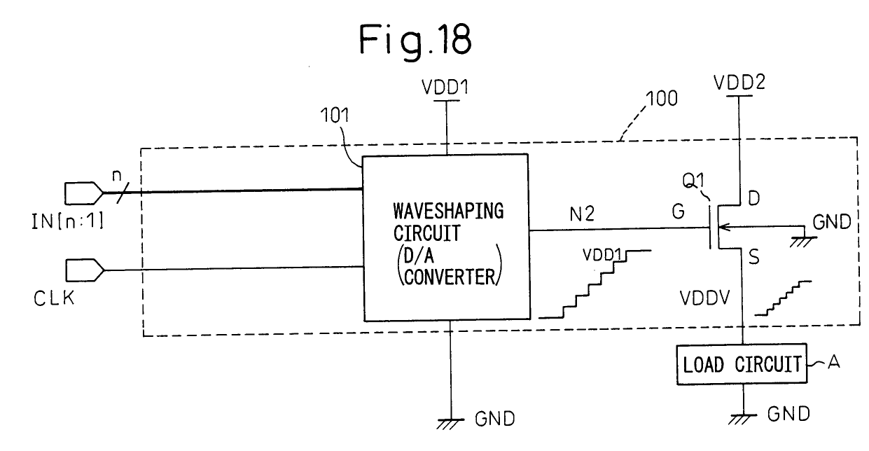

FIG. 18 is a block circuit diagram schematically showing a seventh embodiment of a semiconductor integrated circuit device according to the present invention.

As shown in FIG. 18, in the semiconductor integrated circuit device of the seventh embodiment, the waveshaping circuit 101 is constructed from a D/A converter which controls the output signal (node N2), for example, by an n-bit control signal [n:1]; this facilitates the waveform moderating control and makes it possible to make the waveform further slow. That is, when the waveshaping circuit 101 is constructed by adjusting the transistor size and the number of transistors as shown in FIG. 16, it is difficult to obtain a sufficiently slow waveform; by contrast, when the waveshaping circuit 101 is constructed from a D/A converter as in the seventh embodiment, the waveform can be made sufficiently slow, though the output waveform (N2) of the waveshaping circuit 101 becomes a step voltage. Furthermore, according to the semiconductor integrated circuit device of the seventh embodiment, as the output waveform of the waveshaping circuit 101 can be programmably adjusted, it also becomes possible to change the slope to an optimum value after, for example, evaluating the semiconductor integrated circuit device (LSI).

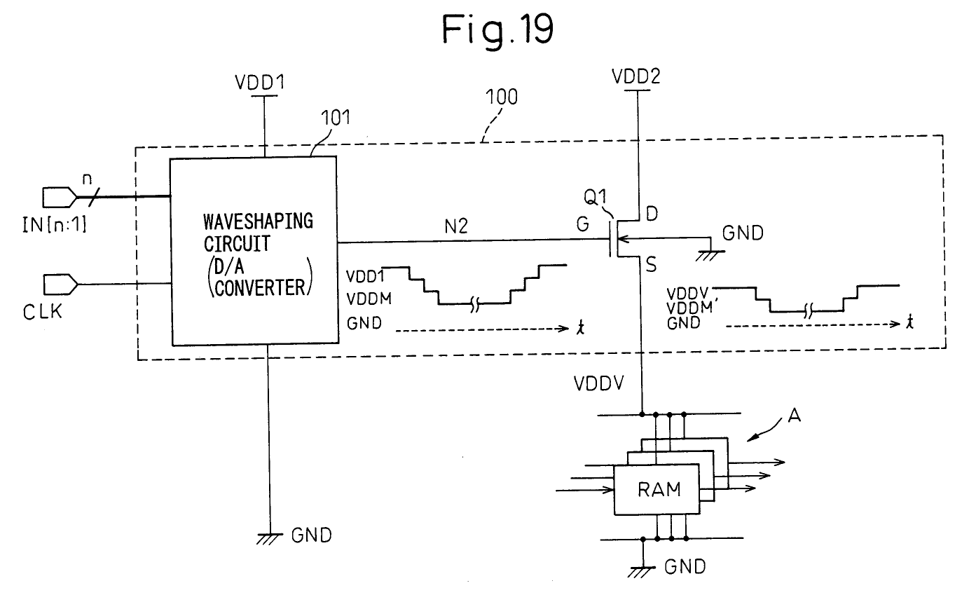

FIG. 19 is a block circuit diagram schematically showing an eighth embodiment of a semiconductor integrated circuit device according to the present invention.

As shown in FIG. 19, in the semiconductor integrated circuit device of the eighth embodiment, the load circuit A is constructed as a RAM (for example, SRAM: Static Random Access Memory), and this RAM (load circuit A) is operated, for example, during backup standby, at a voltage (VDDM′) lower than its normal operating voltage (VDDV). That is, by controlling the n-bit control signal [n:1], the output voltage of the waveshaping circuit 101 constructed from the D/A converter is set to VDDM, and the voltage (pseudo high-potential power supply line VDDV) output from the source of the power supply switch (MT-CMOS switch) Q1 configured as a source follower is set to the voltage (VDDM′) that only guarantees the retention of the stored contents of the load circuit (RAM), thus reducing the power consumption, for example, during backup standby.

To describe the above more specifically, in an SRAM fabricated using a 0.11-μm process, for example, the voltage required to retain stored data is about one half of, for example, the normal supply voltage (for example, 1.3 V); therefore, the power consumption can be reduced by setting the backup standby voltage to about one half of the normal supply voltage. If the load circuit A is constructed from a flip-flop (FF) or the like instead of the RAM such as an SRAM, the voltage for use can be reduced to a level lower than the normal power supply voltage.

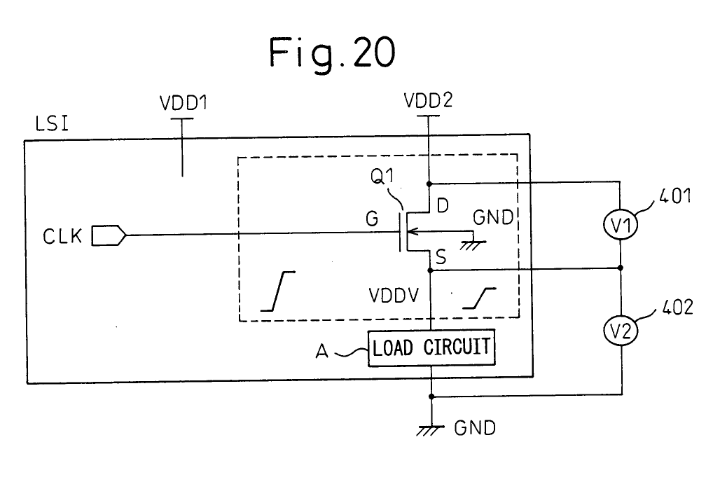

FIG. 20 is a block circuit diagram schematically showing a ninth embodiment of a semiconductor integrated circuit device according to the present invention.

As shown in FIG. 20, in the semiconductor integrated circuit device of the ninth embodiment, the real power supply line (real high-potential power supply line) VDD and the pseudo power supply line (pseudo high-potential power supply line VDDV) are brought outside the semiconductor chip (LSI) so that the voltages of the real power supply line VDD and the pseudo power supply line VDDV can be measured by voltmeters 401 and 402, respectively. This makes possible the evaluation of the actual voltage drop on the real power supply line VDD, the measurement of the ON resistance of the MT-CMOS circuit, etc., and comparisons with simulation values and other investigations can thus be performed.

As described in detail above, according to the semiconductor integrated circuit device of the present invention, existing standard cells can be used, a twin-well process less costly than a triple-well process can be used for the fabrication of the circuit device, and the layout area can be reduced compared with the prior art semiconductor integrated circuit devices. Furthermore, according to the semiconductor integrated circuit device of the present invention, noise occurring at the time of turning ON and OFF a macro circuit can be reduced to a low level so as not to cause a malfunction of other circuits.

Many different embodiments of the present invention may be constructed without departing from the spirit and scope of the present invention, and it should be understood that the present invention is not limited to the specific embodiments described in this specification, except as defined in the appended claims.

What is claimed is:

1. A semiconductor integrated circuit device comprising:
a high-threshold N-channel type MIS field effect transistor connected between a real high-potential power supply line and a pseudo high-potential power supply line; and
a load circuit having a low-threshold P-channel type MIS field effect transistor and a low-threshold N-channel type MIS field effect transistor, wherein:
a first power supply terminal of said load circuit is connected to said pseudo high-potential power supply line, and a second power supply terminal of said load circuit is connected to a real low-potential power supply line.

2. The semiconductor integrated circuit device as claimed in claim 1, wherein a back gate of said low-threshold P-channel type MIS field effect transistor is connected to said pseudo high-potential power supply line, and a back gate of said low-threshold N-channel type MIS field effect transistor is connected to said real low-potential power supply line.

3. The semiconductor integrated circuit device as claimed in claim 1, further comprising:
a waveshaping circuit which receives a control signal for controlling said high-threshold N-channel type MIS field effect transistor, and performs waveshaping so that said control signal rises slowly, and wherein:
an output signal of said waveshaping circuit is supplied to a gate of said high-threshold N-channel type MIS field effect transistor.

4. The semiconductor integrated circuit device as claimed in claim 3, wherein said high-threshold N-channel type MIS field effect transistor is configured as a source follower, and a voltage on said pseudo high-potential power supply line connected to the source of said high-threshold N-channel type MIS field effect transistor rises slowly in response to the slowly rising output signal of said waveshaping circuit supplied to said gate.

5. The semiconductor integrated circuit device as claimed in claim 3, wherein said waveshaping circuit comprises a high-threshold final-stage MIS field effect transistor having a large gate length and a small gate width, or a plurality of high-threshold final-stage MIS field effect transistors connected in series.

6. The semiconductor integrated circuit device as claimed in claim 3, wherein said waveshaping circuit comprises a digital/analog converter.

7. The semiconductor integrated circuit device as claimed in claim 6, wherein said load circuit comprises a memory circuit, and said digital/analog converter outputs a voltage that is lower than a normal operating voltage of said memory and that only guarantees the retention of stored contents, thereby achieving a reduction in backup standby power consumption.

8. A semiconductor integrated circuit device comprising:
a high-threshold N-channel type MIS field effect transistor connected between a real high-potential power supply line and a pseudo high-potential power supply line, said high-threshold N-channel type MIS field effect transistor being controlled by receiving a slowly rising control signal to a gate thereof; and
a load circuit having a low-threshold P-channel type MIS field effect transistor and a low-threshold N-channel type MIS field effect transistor, wherein:
a first power supply terminal of said load circuit is connected to said pseudo high-potential power supply line, and a second power supply terminal of said load circuit is connected to a real low-potential power supply line.

9. A semiconductor integrated circuit device comprising:
a high-threshold MIS field effect transistor of a first conductivity type, connected between a first real power supply line and a first pseudo power supply line;
a load circuit having a low-threshold MIS field effect transistor of said first conductivity type and a low-threshold MIS field effect transistor of a second conductivity type; and
a level conversion circuit which receives a control signal of a first level for controlling said high-threshold MIS field effect transistor of said first conductivity type, and which converts said control signal of said first level into a control signal of a second level and supplies said control signal of said second level to a gate of said high-threshold MIS field effect transistor of said first conductivity type, wherein:
a first power supply terminal of said load circuit is connected to said first pseudo power supply line, and a second power supply terminal of said load circuit is connected to a second real power supply line.

10. The semiconductor integrated circuit device as claimed in claim 9, wherein said high-threshold MIS field effect transistor of said first conductivity type and said level conversion circuit are together constructed as a module.

11. The semiconductor integrated circuit device as claimed in claim 9, wherein said first level is equal to a signal interface level of said load circuit, and said second level is a level greater than said first level.

12. The semiconductor integrated circuit device as claimed in claim 9, wherein said first real power supply line is a real high-potential power supply line, said second real power supply line is a real low-potential power supply line, said first pseudo power supply line is a pseudo high-potential power supply line, and said high-threshold MIS field effect transistor of said first conductivity type is a high-threshold N-channel type MIS field effect transistor, wherein:
a drain of said high-threshold N-channel type MIS field effect transistor is connected to said real high-potential power supply line, a source thereof is connected to said pseudo high-potential power supply line, and a back gate thereof is connected to said real low-potential power supply line.

13. The semiconductor integrated circuit device as claimed in claim 9, wherein said first real power supply line is a real high-potential power supply line, said second real power supply line is a real low-potential power supply line, said first pseudo power supply line is a pseudo high-potential power supply line, and said high-threshold MIS field effect transistor of said first conductivity type is a high-threshold P-channel type MIS field effect transistor, wherein:
a source and back gate of said high-threshold P-channel type MIS field effect transistor are connected to said real high-potential power supply line, and a drain thereof is connected to said pseudo high-potential power supply line.

14. The semiconductor integrated circuit device as claimed in claim 9, further comprising:
a waveshaping circuit which receives the output signal of said level conversion circuit, and performs waveshaping so that the output signal of said level conversion circuit rises slowly, and wherein:
an output signal of said waveshaping circuit is supplied to a gate of said high-threshold MIS field effect transistor of said first conductivity type.

15. The semiconductor integrated circuit device as claimed in claim 14, wherein said high-threshold MIS field effect transistor of said first conductivity type is configured as a source follower, and a voltage on said first pseudo power supply line connected to the source of said high-threshold MIS field effect transistor of said first conductivity type rises slowly in response to the slowly rising output signal of said waveshaping circuit supplied to said gate.

16. The semiconductor integrated circuit device as claimed in claim 9, wherein a physical shield is provided over a signal wiring line from said level conversion circuit to said high-threshold MIS field effect transistor of said first conductivity type.

17. The semiconductor integrated circuit device as claimed in claim 16, wherein said semiconductor integrated circuit device has a multilayered wiring structure, and said shield is formed in a prescribed intermediate wiring layer, while a signal line of a signal interface level of said load circuit is formed in a wiring layer located above said prescribed intermediate wiring layer.

18. The semiconductor integrated circuit device as claimed in claim 14, wherein said waveshaping circuit comprises a high-threshold final-stage MIS field effect transistor having a large gate length and a small gate width, or a plurality of high-threshold final-stage MIS field effect transistors connected in series.

19. The semiconductor integrated circuit device as claimed in claim 14, wherein said waveshaping circuit comprises a digital/analog converter.

20. The semiconductor integrated circuit device as claimed in claim 19, wherein said load circuit comprises a memory circuit, and said digital/analog converter outputs a voltage that is lower than a normal operating voltage of said memory and that only guarantees the retention of stored contents, thereby achieving a reduction in backup standby power consumption.

21. A semiconductor integrated circuit device comprising:
a high-threshold MIS field effect transistor of a first conductivity type, connected between a first real power supply line and a first pseudo power supply line; and
a load circuit having a low-threshold MIS field effect transistor of said first conductivity type and a low-threshold MIS field effect transistor of a second conductivity type, wherein:
a first power supply terminal of said load circuit is connected to said first pseudo power supply line, and a second power supply terminal of said load circuit is connected to a second real power supply line, wherein said first pseudo power supply line is brought outside a chip.

22. A semiconductor integrated circuit device comprising:
a high-threshold MIS field effect transistor of a first conductivity type, connected between a first real power supply line and a first pseudo power supply line; and
a load circuit having a low-threshold MIS field effect transistor of said first conductivity type and a low-threshold MIS field effect transistor of a second conductivity type, wherein:
a first power supply terminal of said load circuit is connected to said first pseudo power supply line, and a second power supply terminal of said load circuit is connected to a second real power supply line, wherein said first real power supply line is brought outside a chip.
